(19) United States
(12) Patent Application Publication
(10) Pub. No.: US 2002/0028394 A1
(43) Pub. Date: Mar. 7, 2002

(54) Method for manufacturing a membrane mask

(75) Inventors: Hitoshi Watanabe, Tokyo (JP); Hiroshi Yano, Tokyo (JP)

Correspondence Address: David L. Fehrman, Morrison & Foerster LLP, 35th Floor, 555 W. 5th Street, Los Angeles, CA, 90013, US

(73) Assignee: ADVANTEST CORPORATION

(21) Appl. No.: 09/946,846

(22) Filed: Sep. 4, 2001

(30) Foreign Application Priority Data
Sep. 4, 2000 (JP) 2000-266555

(51) Int. Cl. C23F 1/00; G03C 5/00; C03C 25/68; C03C 15/00; C25F 3/00; B44C 1/22; G03F 9/00

(52) U.S. Cl. 430/5; 216/41; 216/12; 430/322; 430/323; 430/324

(57) ABSTRACT

The present invention provides a method for manufacturing a mask using a substrate comprising a first, second and third layers, the method comprising : forming one or more openings through the first layer to an extent that a portion of a first surface of the second layer facing the first layer is exposed; wet-etching at least a first portion of the third layer to an extent that a second surface of the second layer facing the third layer is not exposed, the first portion of the third layer corresponding to the openings of the first layer; dry-etching at least a second portion of the third layer to an extent that a portion of the second surface of the second layer facing the third layer is exposed, the second portion of the third layer corresponding to the openings of the first layer; and removing the exposed portion of the second layer such that the openings of the first layer extend through the second layer.

### BACKGROUND OF THE INVENTION

1. Field of the Invention

The present invention relates to a method for manufacturing a membrane mask. In particular, the present invention relates to a mask having a membrane structure, which is manufactured by selective application of wet etching and dry etching processes to a layer of a substrate to avoid damaging the mask during manufacture.

2. Description of the Related Art

FIGS. 1(a) to 1(c) are cross sectional views of a mask showing process steps of a conventional method for manufacturing the mask. As shown in FIGS. 1(a) to 1(c), the mask includes a first layer 202, a second layer 204 and a third layer 206. Referring to FIG. 1(a), an opening 210 is formed through the first and second layer 202 and 204 after performing prior conventional processes. Referring to FIG. 1(b), the structure of the mask becomes membranous by performing wet etching on the third layer 206. The second layer 204 is used as an etching stopper when the structure of the mask becomes membranous by wet-etching the third layer 206.

According to the above described conventional method for manufacturing a mask, as shown in FIG. 1(b), since the second layer 204 is extremely thin, the second layer 204 is easily damaged by the pressure of an etchant for the wet etching process when the structure of the mask becomes membranous by wet-etching the third layer 206. Therefore, as shown in FIG. 1(c), the first layer 202 can be damaged by the etchant through the damaged portion of the second layer 204, so that the opening 210 can also be damaged. Especially, the larger the opening 210 is, the easier it is damaged.

### SUMMARY OF THE INVENTION

Therefore, it is an object of the present invention to provide a method for manufacturing a membrane mask which overcomes the above issues in the related art. This object is achieved by combinations described in the independent claims. The dependent claims define further advantageous and exemplary combinations of the present invention.

According to an aspect of the present invention, a method for manufacturing a mask using a substrate comprising a first, second and third layers, the method comprising: forming one or more openings through the first layer to an extent that a portion of a first surface of the second layer facing the first layer is exposed; wet etching at least a first portion of the third layer to an extent that a second surface of the second layer facing the third layer is not exposed, the first portion of the third layer corresponding to the openings of the first layer; dry-etching at least a second portion of the third layer to an extent that a portion of the second surface of the second layer facing the third layer is exposed, the second portion of the third layer corresponding to the openings of the first layer; and removing the exposed portion of the second layer such that the openings of the first layer extend through the second layer.

The wet-etching may comprise wet-etching at least the first portion of the third layer while keeping the first layer out of contact with an etchant for the wet-etching of the third layer.

The method for manufacturing a mask may further comprise: forming an etch mask on at least a part of the third layer other than the first portion of the third layer corresponding to the openings of the first layer, wherein the wet-etching comprises wet-etching the third layer by using the etch mask as a mask, and wherein the dry-etching comprises dry-etching the third layer to an extent that the portion of the second layer is exposed while removing the etch mask formed on the third layer.

This summary of the invention does not necessarily describe all necessary features so that the invention may also be a sub-combination of these described features.

### BRIEF DESCRIPTION OF THE DRAWINGS

FIGS. 1(a) to 1(c) are cross sectional views of a mask showing process steps of a conventional method for manufacturing the mask. FIGS. 2(a) to 2(h) are cross sectional views of a mask showing process steps of a method for manufacturing the mask according to an embodiment of the present invention.

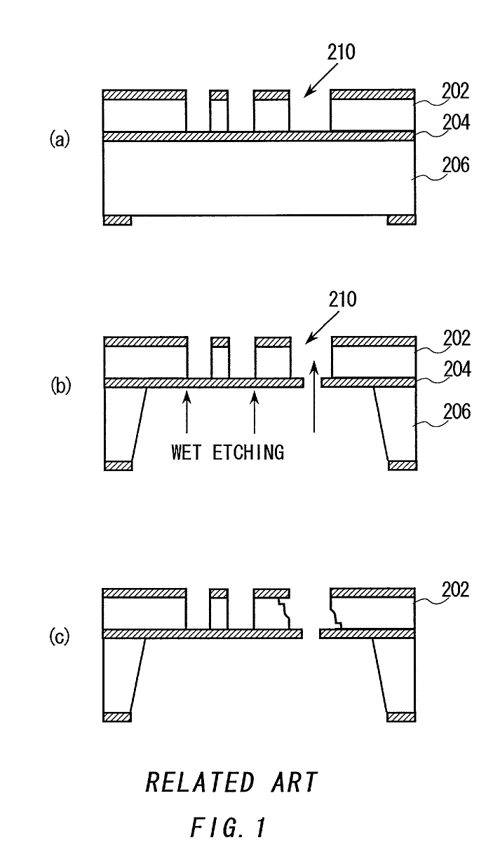

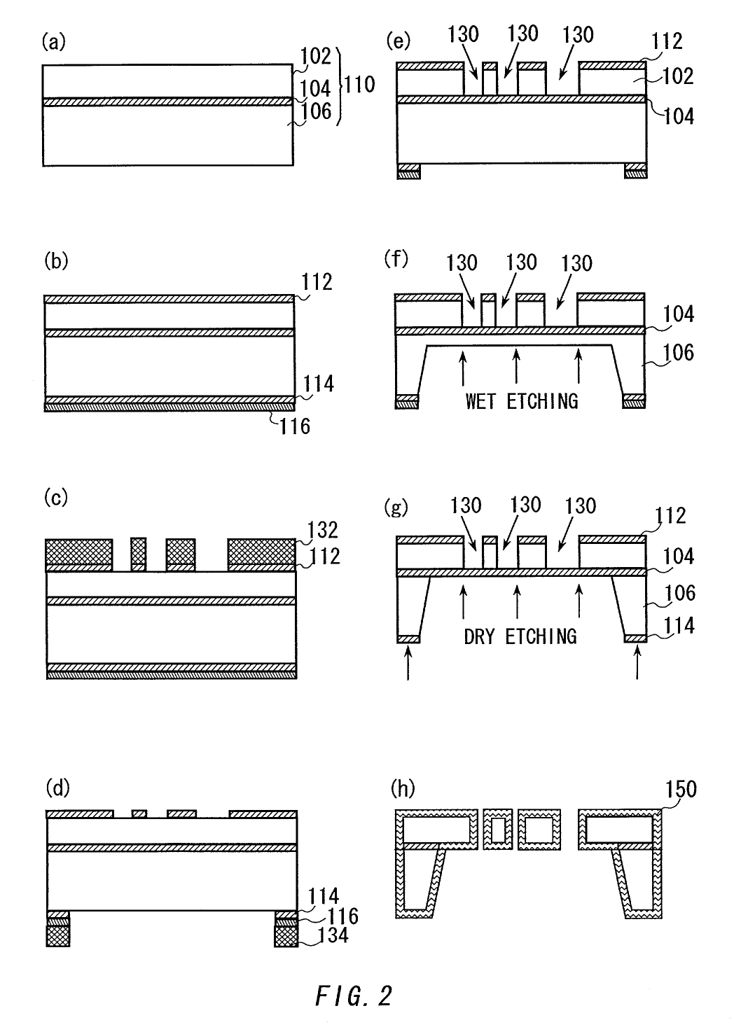

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

FIGS. 2(a) to 2(h) show process steps of a method for manufacturing the mask according to an embodiment of the present invention. As shown in FIG. 2 (a), a substrate 110 is provided and the substrate 110 preferably has a multilayer structure including a first layer 102, a second layer 104 and a third layer 106. According to the present embodiment, the substrate 110 is preferably a Silicon On Insulator (“SOI”) substrate, and the first, second and third layers 102, 104 and 106 are preferably made of silicon (Si), silicon oxide (SiO) and silicon (Si), respectively. The silicon oxide may be silicon dioxide (SiO₂)

FIG. 2(b) shows a process step where passivation layers 112, 114 and 116 are formed on the substrate 110 in order to be used as protecting layers for the following processes described below. In other words, a first passivation layer 112 is formed on the first layer 102, and a second passivation layer 114 is formed on the third layer 106. The first passivation layer 112 is preferably made of a kind of material which can function as a masking layer for a subsequent etching process performed on the first layer 102, as described below. According to the present embodiment, the first and the second passivation layers 112 and 114 are preferably made of SiO (SiO₂) deposited on the first and third layers 102 and 106, respectively, by a chemical vapor deposition (“CVD”) process. According to another embodiment of the present invention, the first and the second passivation layers 112 and 114 may be formed by a thermal oxidation process on the first and third layers 102 and 106, respectively. A third passivation layer 116 is formed on the second passivation layer 114. The third passivation layer 116 is preferably made of a kind of material which can function as an etch mask for a subsequent etching process performed on the third layer 106, as described below. According to the present embodiment, the third passivation layer 116 is preferably made of silicon nitride (SiN, Si₃N₄).

FIG. 2(c) shows a process step for forming a predetermined pattern on the first passivation layer 112. Resist is applied and coated on the first passivation layer 112, and a desired first resist pattern 132 is formed by a lithography process on the resist film. The resist pattern 132 preferably corresponds to a pattern of openings which will be formed on the first layer 112 by a subsequent process. Then, the first passivation layer 112 is patterned to have a desired pattern of openings by etching the first passivation layer 112 with the first resist pattern 132 used as a mask.

FIG. 2(d) shows a process step for making a desired pattern on the second and third passivation layers 114 and 116. First, the first resist pattern 132 is removed. Then, resist is applied and coated on the third passivation layer 116, and a desired second resist pattern 134 is formed by a lithography process on the resist film. As shown in FIGS. 2(c) and 2(d), the second resist pattern 134 preferably has an opening which extends over at least a portion of the third layer 106 corresponding to the openings of the first passivation layer 112. In other words, the opening in the second resist pattern 134 is at least coextensive with the openings in the first resist pattern 132, which serves as a mask for patterning the first passivation layer 112 with a desired pattern of openings, as described above. Then, the second and third passivation layers 114 and 116 are patterned to have desired patterns by etching the second and third passivation layers 114 and 116 with the second resist pattern 134 used as a mask.

FIG. 2(e) shows a process step for making openings 130 in the first layer 102. The openings 130 are preferably formed to expose a portion of the surface of the second layer 104 facing the first layer 102. The openings 130 are formed by etching the first layer 102 with the first passivation layer 112 as a mask, which is patterned to have the desired pattern according to the process step shown in FIG. 2(c). The openings 130 are preferably formed by anisotropic dry etching. The openings 130 are preferably formed so as to be nearly vertical (i.e., perpendicular) to a plane that is defined by the respective surfaces of the first and second layers 102 and 104 that are contacted, and so as to become wider along the direction of the etching of the first layer 102.

FIG. 2(f) shows a process step for wet etching the portion of the third layer 106 corresponding to the openings 130 of the first layer 102. The third layer 106 is wet-etched with the second and third passivation layer 114 and 116 as masks, which are patterned to have the desired pattern, while the first layer 102 is kept out of contact with the etchant for the wet etching of the third layer 106. For example, it is possible to use a jig to protect the first layer 102 while the third layer 106 is wet-etched, and to use a wet etching apparatus, which wet etches on only one side of a wafer, to wet-etch the third layer 106. Alternatively, it is possible to vaporize the etchant and to wet-etch the third layer 106 with the vaporized etchant. According to the present embodiment, the third layer 106 is wet-etched by using potassium hydroxide (KOH) as the etchant. Further, it is preferable to wet-etch the third layer 106 so that the surface of the second layer 104 facing the third layer 106 is not exposed by the wet etching. Specifically, the third layer 106 is wet-etched until the combination of the second layer 104 and the remaining portion of the third layer 106 has enough thickness at least to bear the pressure of the etchant. It is desirable for the remaining layer which includes the second layer 104 and the remaining portion of the third layer 106 to be intact and present at the openings 130 after the wet etching.

FIG. 2(g) shows a process step for performing dry etching on at least a portion of the third layer 106 corresponding to the openings 130. At least the portion of the third layer 106 corresponding to the openings 130 is preferably dry-etched until the surface of the second layer 104 facing the third layer 106 is exposed. The dry etching may be either isotropic or anisotropic. It is preferable to perform the dry etching on the third layer 106 under the condition where the second layer 104 functions as an etching stopper. According to another embodiment of the present invention, the third passivation layer 116 may also be removed while the third layer 106 is dry-etched. If the third layer 106 and the third passivation layer 116 are etched at the same time, it is possible to skip a separate process step for only removing the third passivation layer 116.

FIG. 2(h) shows a process step for forming a conductive passivation film 150. Referring back to FIG. 2(g), first, the first and second passivation layer 112 and 114, and the exposed portion of the second layer 104 are removed. Then, conductive material is deposited on the mask 100 by, for example, sputtering so that the process for manufacturing the mask 100 is completed.

According to the method for manufacturing a mask of the present invention, even when the second layer 104 is extremely thin, it is possible to make a membrane-structured mask 100 by removing a predetermined portion of the third layer 106 through selective wet and dry etching processes without damaging the second layer 104. In other words, it is possible to make a membrane-structured mask 100 without damaging the openings 130 nor performing complicated process steps. Therefore, in case of shaping a cross section of a beam of charged particles, such as an electron beam, by irradiating the beam through the mask 100, it is possible to shape the cross section of the beam with high precision by using the openings 130 which are shaped with high precision according to the present invention.

As apparent from the above detailed description, according to the present invention, it is possible to manufacture a mask with an opening without damaging the openings 130 nor performing complicated process steps.

Although the present invention has been described by way of exemplary embodiments, it should be understood that many changes and substitutions may be made by those skilled in the art without departing from the spirit and the scope of the present invention which is defined only by the appended claims.

What is claimed is:

1. A method for manufacturing a mask using a substrate comprising a first, second and third layers, the method comprising :
forming one or more openings through said first layer to an extent that a portion of a first surface of said second layer facing said first layer is exposed;
wet-etching at least a first portion of said third layer to an extent that a second surface of said second layer facing said third layer is not exposed, said first portion of said third layer corresponding to said openings of said first layer;
dry-etching at least a second portion of said third layer to an extent that a portion of said second surface of said second layer facing said third layer is exposed, said second portion of said third layer corresponding to said openings of said first layer; and
removing said exposed portion of said second layer such that said openings of said first layer extend through said second layer.

2. A method for manufacturing a mask as claimed in claim 1, wherein said wet-etching comprises wet-etching at least said first portion of said third layer while keeping said first layer out of contact with an etchant for said wet-etching of said third layer.

3. A method for manufacturing a mask as claimed claim 1, further comprising:
forming an etch mask on at least a part of said third layer other than said first portion of said third layer corresponding to said openings of said first layer, wherein said wet-etching comprises wet-etching said third layer by using said etch mask as a mask, and wherein said dry-etching comprises dry-etching said third layer to an extent that said portion of said second layer is exposed while removing said etch mask formed on said third layer.
